(19) United States
(12) Patent Application Publication
(10) Pub. No.: US 2025/0017121 A1
(43) Pub. Date: Jan. 9, 2025

(54) RESISTIVE MEMORY STRUCTURE AND MANUFACTURING METHOD THEREOF

(71) Applicant: United Microelectronics Corp., Hsinchu (TW)

(72) Inventors: Wen-Jen Wang, Tainan City (TW); Yu-Huan Yeh, Hsinchu City (TW); Chuan-Fu Wang, Miaoli County (TW)

(73) Assignee: United Microelectronics Corp., Hsinchu (TW)

(21) Appl. No.: 18/449,716

(22) Filed: Aug. 15, 2023

(30) Foreign Application Priority Data
Jul. 3, 2023 (TW) 112124688

(51) Int. Cl. H10N 70/00; H10B 63/00

(52) U.S. Cl. CPC H10N 70/068; H10B 63/80; H10N 70/063; H10N 70/841; H10N 70/8833

(57) ABSTRACT

A resistive memory structure including a substrate, a dielectric layer, a conductive plug, a resistive memory device, a spacer, and a protective layer is provided. The dielectric layer is located on the substrate. The conductive plug is located in the dielectric layer. The conductive plug has a protrusion portion located outside the dielectric layer. The resistive memory device is located on the conductive plug. The resistive memory device includes a first electrode, a variable resistance layer, and a second electrode. The first electrode is located on the conductive plug. The variable resistance layer is located on the first electrode. The second electrode is located on the variable resistance layer. The spacer is located on a sidewall of the resistive memory device. The protective layer is located on a sidewall of the protrusion portion and between the first electrode and the dielectric layer.

### CROSS-REFERENCE TO RELATED APPLICATION

This application claims the priority benefit of Taiwan application serial no. 112124688, filed on Jul. 3, 2023. The entirety of the above-mentioned patent application is hereby incorporated by reference herein and made a part of this specification.

### BACKGROUND

### Technical Field

The invention relates to a semiconductor structure and a manufacturing method thereof, and particularly relates to a resistive memory structure and a manufacturing method thereof.

### Description of Related Art

The resistive memory device has the potential advantages such as low power consumption and high-speed operation, so the resistive memory device is very suitable as the next-generation memory device. However, how to further improve the reliability and data retention capacity of the resistive memory device is the goal of continuous efforts.

### SUMMARY

The invention provides a resistive memory structure and a manufacturing method thereof, which can improve the reliability and data retention capacity of the resistive memory device.

The invention provides a resistive memory structure, which includes a substrate, a dielectric layer, a conductive plug, a resistive memory device, a spacer, and a protective layer. The dielectric layer is located on the substrate. The conductive plug is located in the dielectric layer. The conductive plug has a protrusion portion located outside the dielectric layer. The resistive memory device is located on the conductive plug. The resistive memory device includes a first electrode, a variable resistance layer, and a second electrode. The first electrode is located on the conductive plug. The variable resistance layer is located on the first electrode. The second electrode is located on the variable resistance layer. The spacer is located on the sidewall of the resistive memory device. The protective layer is located on the sidewall of the protrusion portion and between the first electrode and the dielectric layer.

According to an embodiment of the invention, in the resistive memory structure, the top surface of the conductive plug may be higher than the top surface of the dielectric layer.

According to an embodiment of the invention, in the resistive memory structure, the top surface of the conductive plug may be coplanar with the top surface of the protective layer.

According to an embodiment of the invention, in the resistive memory structure, the protective layer may be in direct contact with the first electrode, the dielectric layer, and the protrusion portion.

According to an embodiment of the invention, in the resistive memory structure, the spacer may be in direct contact with the first electrode, the variable resistance layer, and the second electrode.

According to an embodiment of the invention, in the resistive memory structure, the spacer may be further in direct contact with the protective layer.

According to an embodiment of the invention, in the resistive memory structure, the spacer may completely cover the sidewall of the first electrode.

According to an embodiment of the invention, in the resistive memory structure, the spacer may completely cover the sidewall of the variable resistance layer.

According to an embodiment of the invention, in the resistive memory structure, the top of the spacer may be lower than the top surface of the second electrode.

According to an embodiment of the invention, in the resistive memory structure, the material of the first electrode is, for example, titanium (Ti).

According to an embodiment of the invention, in the resistive memory structure, the material of the variable resistance layer is, for example, tantalum oxide (TaO) or hafnium oxide.

According to an embodiment of the invention, in the resistive memory structure, the material of the second electrode is, for example, titanium.

According to an embodiment of the invention, in the resistive memory structure, the material of the spacer is, for example, silicon nitride.

According to an embodiment of the invention, in the resistive memory structure, the material of the protective layer is, for example, silicon nitride.

The invention provides a manufacturing method of a resistive memory structure, which includes the following steps. A substrate is provided. A dielectric layer is formed on the substrate. A conductive plug is formed in the dielectric layer. The conductive plug has a protrusion portion located outside the dielectric layer. A resistive memory device is formed on the conductive plug. The resistive memory device includes a first electrode, a variable resistance layer, and a second electrode. The first electrode is located on the conductive plug. The variable resistance layer is located on the first electrode. The second electrode is located on the variable resistance layer. A spacer is formed on the sidewall of the resistive memory device. A protective layer is formed on the sidewall of the protrusion portion and between the first electrode and the dielectric layer.

According to an embodiment of the invention, in the manufacturing method of the resistive memory structure, the method of forming the conductive plug may include the following steps. A protective material layer is formed on the dielectric layer. An opening is formed in the protective material layer and the dielectric layer. A conductive layer is formed on the protective material layer and in the opening. The conductive layer located outside the opening is removed to form the conductive plug.

According to an embodiment of the invention, in the manufacturing method of the resistive memory structure, the method of removing the conductive layer located outside the opening is, for example, a chemical mechanical polishing (CMP) method.

According to an embodiment of the invention, in the manufacturing method of the resistive memory structure, the method of forming the spacer and the protective layer may include the following steps. A spacer material layer is formed on the resistive memory device and the protective material layer. An etch back process is performed on the spacer material layer and the protective material layer to form the spacer and the protective layer.

According to an embodiment of the invention, in the manufacturing method of the resistive memory structure, the etch back process is, for example, a dry etching process.

According to an embodiment of the invention, in the manufacturing method of the resistive memory structure, the protective layer may be in direct contact with the first electrode, the dielectric layer, and the protrusion portion.

Based on the above description, in the resistive memory structure and the manufacturing method thereof according to the invention, the protective layer is located on the sidewall of the protrusion portion and between the first electrode and the dielectric layer, thereby preventing the ions (e.g., oxygen ions) in the dielectric layer from diffusing into the first electrode and the variable resistance layer. Therefore, the reliability and data retention capacity of the resistive memory device can be improved.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1H are cross-sectional views of a manufacturing process of a resistive memory structure according to some embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. In fact, the dimensions of the various features may be arbitrarily increased or reduced for clarity of discussion.

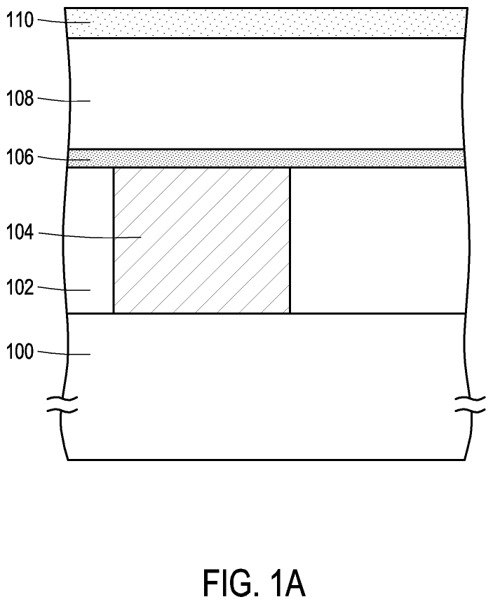

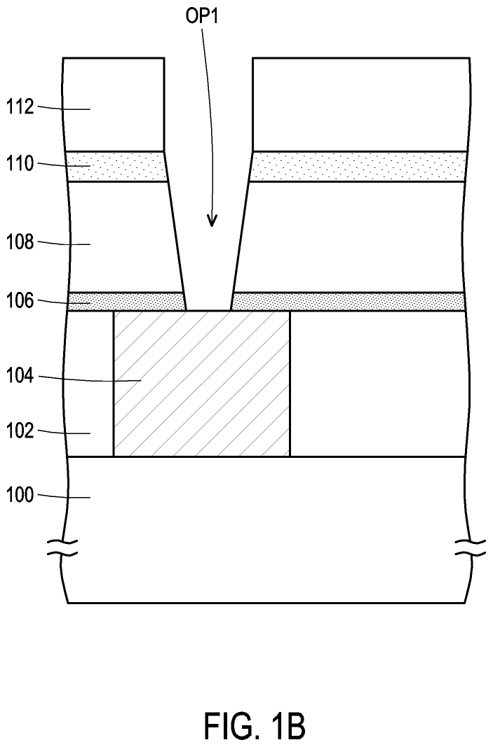

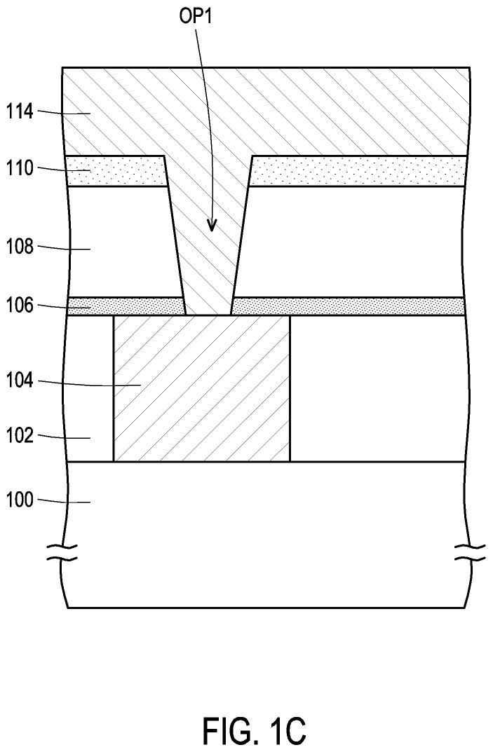

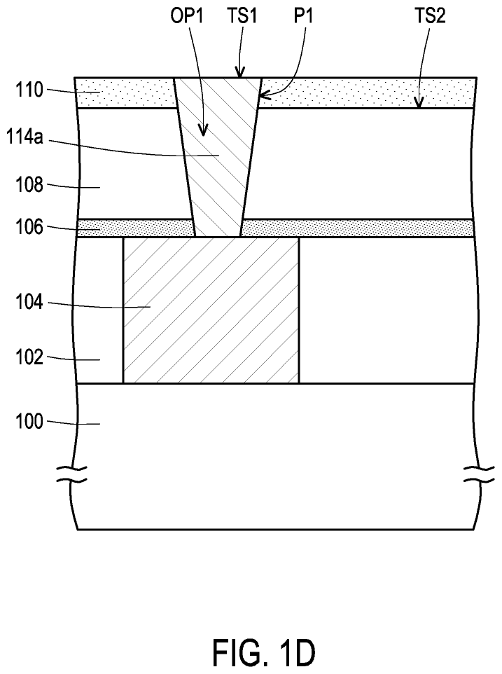

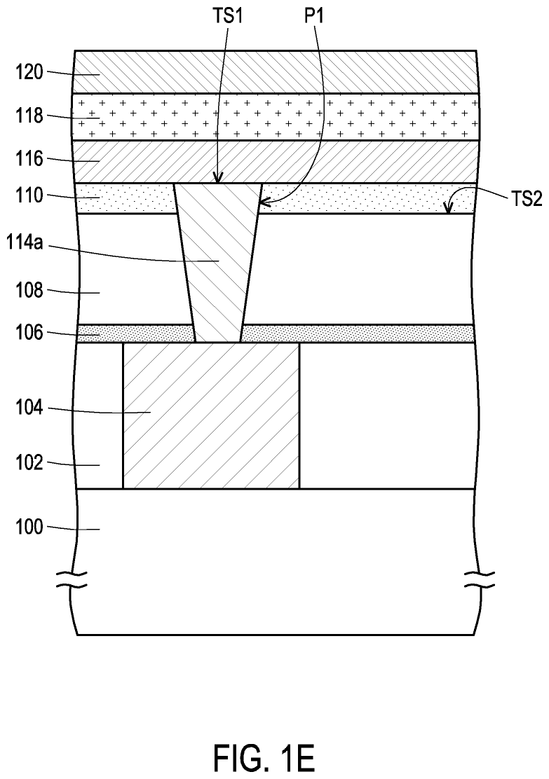

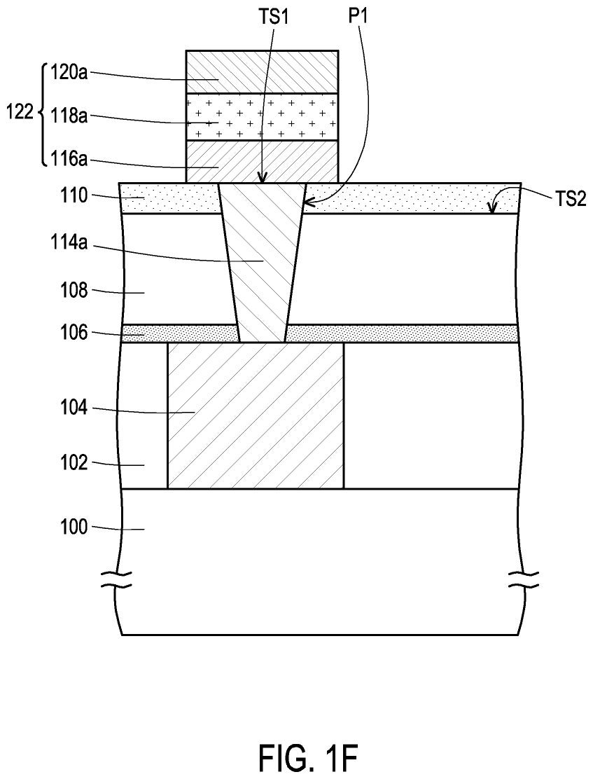

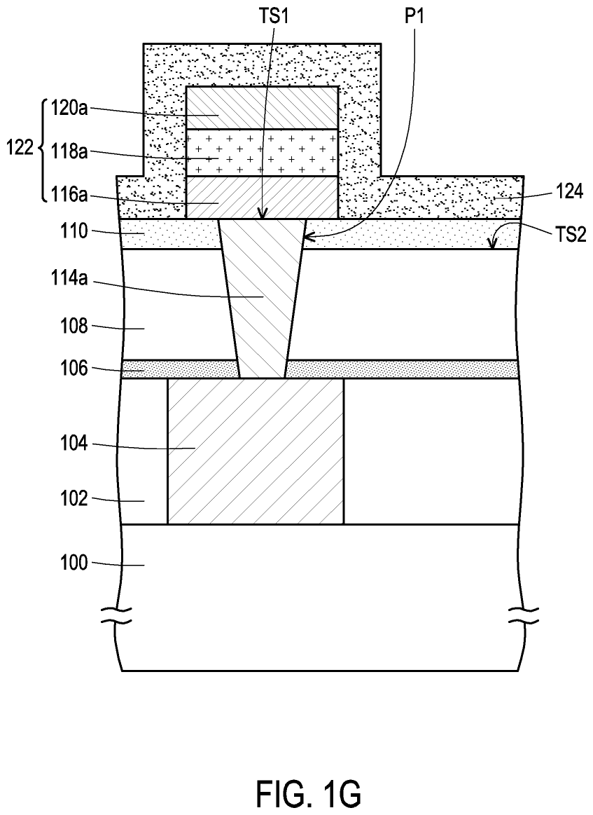

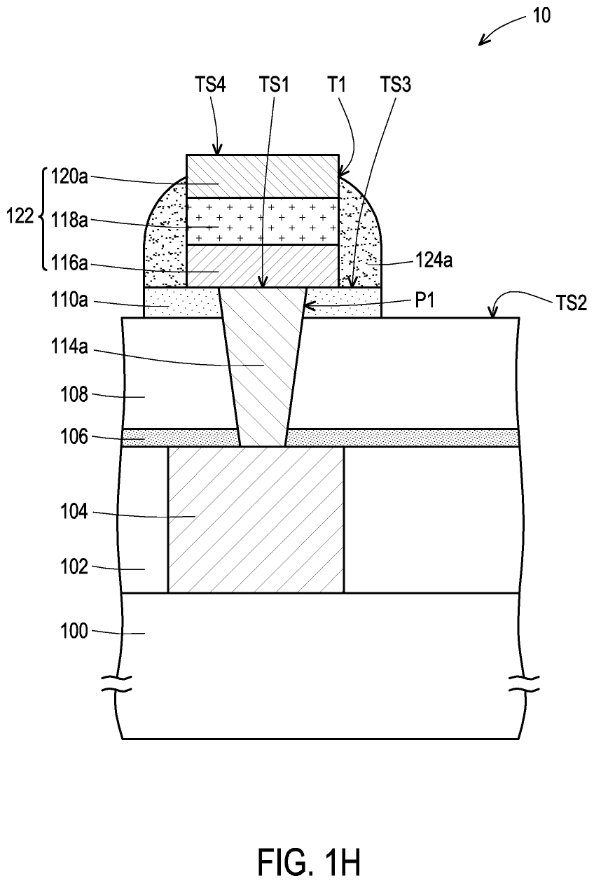

FIG. 1A to FIG. 1H are cross-sectional views of a manufacturing process of a resistive memory structure according to some embodiments of the invention.

Referring to FIG. 1A, a substrate 100 is provided. The substrate 100 may be a semiconductor substrate such as a silicon substrate. In some embodiments, a dielectric layer 102 may be formed on the substrate 100. The material of the dielectric layer 102 is, for example, silicon oxide, a low dielectric constant (low-k) dielectric material, or an ultra low-k (ULK) dielectric material. The method of forming the dielectric layer 102 is, for example, a chemical vapor deposition (CVD) method. In some embodiments, an interconnect structure 104 may be formed in the dielectric layer 102. In some embodiments, the interconnect structure 104 may be a conductive line. The material of the interconnect structure 104 is, for example, a conductive material such as copper. In some embodiments, the interconnect structure 104 may be formed by an interconnect process.

In addition, although not shown in FIG. 1A, the substrate 100 may have required components thereon, such as semiconductor devices (e.g., active devices and/or passive devices), other dielectric layers, and/or other interconnect structures, and the description thereof is omitted here. Furthermore, the interconnect structure 104 may be electrically connected to a corresponding interconnect structure (not shown) or a corresponding semiconductor device (not shown).

A stop layer 106 may be formed on the dielectric layer 102 and the interconnect structure 104. The material of the stop layer 106 is, for example, nitrogen doped silicon carbide (NDC) such as silicon carbonitride (SiCN). The method of forming the stop layer 104 is, for example, a CVD method.

A dielectric layer 108 is formed on the substrate 100. In some embodiments, the dielectric layer 108 may be formed on the stop layer 106. The material of the dielectric layer 108 is, for example, silicon oxide, a low-k dielectric material, or an ultra low-k dielectric material. The method of forming the dielectric layer 108 is, for example, a CVD method.

A protective material layer 110 may be formed on the dielectric layer 108. The material of the protective material layer 110 is, for example, silicon nitride. The method of forming the protective material layer 110 is, for example, a CVD method.

Referring to FIG. 1B, a patterned photoresist layer 112 may be formed on the protective material layer 110. The patterned photoresist layer 112 may be formed by a lithography process.

A portion of the protective material layer 110, a portion of the dielectric layer 108, and a portion of the stop layer 106 may be removed by using the patterned photoresist layer 112 as a mask to form an opening OP1. Therefore, the opening OP1 may be formed in the protective material layer 110, the dielectric layer 108, and the stop layer 106. In some embodiments, the opening OP1 may expose the interconnect structure 104.

Referring to FIG. 1C, the patterned photoresist layer 112 may be removed. The method of removing the patterned photoresist layer 112 is, for example, a dry stripping method or a wet stripping method.

A conductive layer 114 may be formed on the protective material layer 110 and in the opening OP1. The material of the conductive layer 114 is, for example, a conductive material such as tungsten. The method of forming the conductive layer 114 is, for example, a CVD method.

Referring to FIG. 1D, the conductive layer 114 located outside the opening OP1 may be removed to form a conductive plug 114a. Therefore, the conductive plug 114a may be formed in the dielectric layer 108. The conductive plug 114a may be further formed in the protective material layer 110 and the stop layer 106. The conductive plug 114a has a protrusion portion P1 located outside the dielectric layer 108. The top surface TS1 of the conductive plug 114a may be higher than the top surface TS2 of the dielectric layer 108. The conductive plug 114a may be electrically connected to the interconnect structure 104. In some embodiments, the conductive plug 114a may be a conductive via. In some embodiments, the method of removing the conductive layer 114 located outside the opening OP1 is, for example, a CMP method.

Referring to FIG. 1E, an electrode material layer 116, a variable resistance material layer 118, and an electrode material layer 120 may be sequentially formed on the conductive plug 114a and the protective material layer 110. The material of the electrode material layer 116 is, for example, a conductive material such as titanium. The method of forming the electrode material layer 116 is, for example, a physical vapor deposition (PVD) method. The material of the variable resistance material layer 118 may be metal oxide. In some embodiments, the material of the variable resistance material layer 118 is, for example, tantalum oxide or hafnium oxide. The method of forming the variable resistance material layer 118 is, for example, a PVD method. The material of the electrode material layer 120 is, for example, a conductive material such as titanium. The method for forming the electrode material layer 120 is, for example, a PVD method.

Referring to FIG. 1F, the electrode material layer 120, the variable resistance material layer 118, and the electrode material layer 116 may be patterned to form an electrode 120a, a variable resistance layer 118a, and an electrode 116a. Therefore, a resistive memory device 122 may be formed on the conductive plug 114a. In some embodiments, the resistive memory device 122 may be further formed on the protective material layer 110. The resistive memory device 122 includes the electrode 116a, the variable resistance layer 118a, and the electrode 120a. The electrode 116a is located on the conductive plug 114a. The electrode 116a may be electrically connected to the conductive plug 114a. The material of the electrode 116a is, for example, a conductive material such as titanium. The variable resistance layer 118a is located on the electrode 116a. The material of the variable resistance layer 118a may be metal oxide. In some embodiments, the material of the variable resistance layer 118a is, for example, tantalum oxide or hafnium oxide. The electrode 120a is located on the variable resistance layer 118a. The material of the electrode 120a is, for example, a conductive material such as titanium.

Referring to FIG. 1G, a spacer material layer 124 may be formed on the resistive memory device 122 and the protective material layer 110. The material of the spacer material layer 124 is, for example, silicon nitride. The method of forming the spacer material layer 124 is, for example, a CVD method.

Referring to FIG. 1H, an etch back process is performed on the spacer material layer 124 and the protective material layer 110 to form a spacer 124a and a protective layer 110a. Therefore, the spacer 124a may be formed on the sidewall of the resistive memory device 122, and the protective layer 110a may be formed on the sidewall of the protrusion portion P1 and between the electrode 116a and the dielectric layer 108. The protective layer 110a may be further formed between the spacer 124a and the dielectric layer 108. In addition, since the protective layer 110a is located on the sidewall of the protrusion portion P1 and between the electrode 116a and the dielectric layer 108, the ions (e.g., oxygen ions) in the dielectric layer 108 can be prevented from diffusing into the electrode 116a and the variable resistance layer 118a. Therefore, the reliability and data retention capacity of the resistive memory device 122 can be improved. In some embodiments, the etch back process is, for example, a dry etch process.

The protective layer 110a may be in direct contact with the electrode 116a, the dielectric layer 108, and the protrusion portion P1. The top surface TS1 of the conductive plug 114a may be coplanar with the top surface TS3 of the protective layer 110a. The material of the protective layer 110a is, for example, silicon nitride.

The spacer 124a may be in direct contact with the electrode 116a, the variable resistance layer 118a, and the electrode 120a. The spacer 124a may be further in direct contact with the protective layer 110a. The spacer 124a may completely cover the sidewall of the electrode 116a. The spacer 124a may completely cover the sidewall of the variable resistance layer 118a. The top T1 of the spacer 124a may be lower than the top surface TS4 of the electrode 120a. The material of the spacer 124a is, for example, silicon nitride.

Hereinafter, the resistive memory structure 10 of the above embodiments will be described with reference to FIG. 1H. In addition, although the method for forming the resistive memory structure 10 is described by taking the above method as an example, the invention is not limited thereto.

Referring to FIG. 1H, the resistive memory structure 10 includes a substrate 100, a dielectric layer 108, a conductive plug 114a, a resistive memory device 122, a spacer 124a, and a protective layer 110a. The dielectric layer 108 is located on the substrate 100. The conductive plug 114a is located in the dielectric layer 108. The conductive plug 114a has a protrusion portion P1 located outside the dielectric layer 108. The resistive memory device 122 is located on the conductive plug 114a. The resistive memory device 122 includes an electrode 116a, a variable resistance layer 118a, and an electrode 120a. The electrode 116a is located on the conductive plug 114a. The variable resistance layer 118a is located on the electrode 116a. The electrode 120a is located on the variable resistance layer 118a. The spacer 124a is located on the sidewall of the resistive memory device 122. The protective layer 110a is located on the sidewall of the protrusion portion P1 and between the electrode 116a and the dielectric layer 108.

In some embodiments, the resistive memory structure 10 may further include at least one of a dielectric layer 102, an interconnect structure 104, and a stop layer 106. The dielectric layer 102 is located between the dielectric layer 108 and the substrate 100. The interconnect structure 104 is located in the dielectric layer 102. The stop layer 106 is located between the dielectric layer 108 and the dielectric layer 102 and between the dielectric layer 108 and the interconnect structure 104. The conductive plug 114a may pass through the stop layer 106 to connect to the interconnect structure 104.

In addition, the details (e.g., the material, the arrangement, the forming method, and the effect) of each component in the resistive memory structure 10 have been described in detail in the above embodiments, and the description thereof is not repeated here.

Based on the above embodiments, in the resistive memory structure 10 and the manufacturing method thereof, the protective layer 110a is located on the sidewall of the protrusion portion P1 and between the electrode 116a and the dielectric layer 108, thereby preventing the ions (e.g., oxygen ions) in the dielectric layer 108 from diffusing into the electrode 116a and the variable resistance layer 118a. Therefore, the reliability and data retention capacity of the resistive memory device 122 can be improved.

In summary, in the resistive memory structure and the manufacturing method thereof of the aforementioned embodiments, since the protective layer can prevent the ions (e.g., oxygen ions) in the dielectric layer from diffusing into the electrode and the variable resistance layer of the resistive memory device, the reliability and data retention capacity of the resistive memory device can be improved.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A resistive memory structure, comprising:
a substrate;
a dielectric layer located on the substrate;
a conductive plug located in the dielectric layer and having a protrusion portion located outside the dielectric layer;
a resistive memory device located on the conductive plug and comprising:
a first electrode located on the conductive plug;
a variable resistance layer located on the first electrode; and
a second electrode located on the variable resistance layer;
a spacer located on a sidewall of the resistive memory device; and
a protective layer located on a sidewall of the protrusion portion and between the first electrode and the dielectric layer.

2. The resistive memory structure according to claim 1, wherein a top surface of the conductive plug is higher than a top surface of the dielectric layer.

3. The resistive memory structure according to claim 1, wherein a top surface of the conductive plug is coplanar with a top surface of the protective layer.

4. The resistive memory structure according to claim 1, wherein the protective layer is in direct contact with the first electrode, the dielectric layer, and the protrusion portion.

5. The resistive memory structure according to claim 1, wherein the spacer is in direct contact with the first electrode, the variable resistance layer, and the second electrode.

6. The resistive memory structure according to claim 5, wherein the spacer is further in direct contact with the protective layer.

7. The resistive memory structure according to claim 1, wherein the spacer completely covers a sidewall of the first electrode.

8. The resistive memory structure according to claim 1, wherein the spacer completely covers a sidewall of the variable resistance layer.

9. The resistive memory structure according to claim 1, wherein a top of the spacer is lower than a top surface of the second electrode.

10. The resistive memory structure according to claim 1, wherein a material of the first electrode comprises titanium.

11. The resistive memory structure according to claim 1, wherein a material of the variable resistance layer comprises tantalum oxide or hafnium oxide.

12. The resistive memory structure according to claim 1, wherein a material of the second electrode comprises titanium.

13. The resistive memory structure according to claim 1, wherein a material of the spacer comprises silicon nitride.

14. The resistive memory structure according to claim 1, wherein a material of the protective layer comprises silicon nitride.

15. A manufacturing method of a resistive memory structure, comprising:
providing a substrate;
forming a dielectric layer on the substrate;
forming a conductive plug in the dielectric layer, wherein the conductive plug has a protrusion portion located outside the dielectric layer;
forming a resistive memory device on the conductive plug, wherein the resistive memory device comprises:
a first electrode located on the conductive plug;
a variable resistance layer located on the first electrode; and
a second electrode located on the variable resistance layer;
forming a spacer on a sidewall of the resistive memory device; and
forming a protective layer on a sidewall of the protrusion portion and between the first electrode and the dielectric layer.

16. The manufacturing method of the resistive memory structure according to claim 15, wherein a method of forming the conductive plug comprises:
forming a protective material layer on the dielectric layer;
forming an opening in the protective material layer and the dielectric layer;
forming a conductive layer on the protective material layer and in the opening; and
removing the conductive layer located outside the opening to form the conductive plug.

17. The manufacturing method of the resistive memory structure according to claim 16, wherein a method of removing the conductive layer located outside the opening comprises a chemical mechanical polishing method.

18. The manufacturing method of the resistive memory structure according to claim 16, wherein a method of forming the spacer and the protective layer comprises:
forming a spacer material layer on the resistive memory device and the protective material layer; and
performing an etch back process on the spacer material layer and the protective material layer to form the spacer and the protective layer.

19. The manufacturing method of the resistive memory structure according to claim 18, wherein the etch back process comprises a dry etching process.

20. The manufacturing method of the resistive memory structure according to claim 15, wherein the protective layer is in direct contact with the first electrode, the dielectric layer, and the protrusion portion.
